(19) United States
(12) Patent Application Publication
(10) Pub. No.: US 2025/0220996 A1
(43) Pub. Date: Jul. 3, 2025

(54) SEMICONDUCTOR DEVICE

(71) Applicant: Samsung Electronics Co., Ltd., Suwon-si (KR)

(72) Inventors: Chulmin CHOI, Suwon-si (KR); Sanghoon KIM, Suwon-si (KR); Seungjae BAIK, Suwon-si (KR); Jaeduk LEE, Suwon-si (KR)

(73) Assignee: Samsung Electronics Co., Ltd., Suwon-si (KR)

(21) Appl. No.: 18/752,895

(22) Filed: Jun. 25, 2024

(30) Foreign Application Priority Data
Dec. 29, 2023 (KR) 10-2023-0197703

(51) Int. Cl. H01L 29/10; H01L 21/30; H01L 29/78; H10B 12/00

(52) U.S. Cl. CPC H10D 62/235; H01L 21/3003; H10B 12/50; H10D 30/63

(57) ABSTRACT

A semiconductor device includes a hydrogen rich layer interposed between a common source layer and an uppermost one of gate electrodes in a cell region, wherein a concentration of hydrogen (H) contained in the hydrogen rich layer is greater than a concentration of hydrogen (H) contained in the gate electrodes. Accordingly, hydrogen (H) may be effectively supplied to a channel hole during a high temperature process for forming a cell region. Thus, an issue of supply deficiency of hydrogen (H), which may occur according to an increase in the number of layers of a semiconductor device, may be improved, and operation reliability of the semiconductor device may be improved.

### CROSS-REFERENCE TO RELATED APPLICATION

This application is based on and claims ranking under 35 U.S.C. § 119 to Korean Patent Application No. 10-2023-0197703, filed on Dec. 29, 2023 in the Korean Intellectual Property office, the disclosure of which is incorporated by reference herein in its entirety.

### BACKGROUND

The inventive concepts relate to semiconductor devices. The inventive concepts relate to semiconductor devices including a memory string arranged in the vertical direction.

In an electronic system requiring a data storage, semiconductor devices capable of storing a large amount of data are required. As one of the methods to increase data storage capacity of semiconductor devices, semiconductor devices including three-dimensionally arranged memory cells instead of two-dimensionally arranged memory cells have been proposed. In addition, a semiconductor device, in which a portion of the semiconductor device is formed on a first substrate, another portion of the semiconductor device is formed on a second substrate, and the first substrate is bonded to the second substrate, has been proposed.

### SUMMARY

The inventive concepts provide semiconductor memory devices having good dynamic characteristics and improved reliability.

In addition, the issues to be solved by the technical ideas of the inventive concepts are not limited to those mentioned above, and other issues may be clearly understood by those of ordinary skill in the art from the following descriptions.

The inventive concepts provide semiconductor packages as described below.

According to an example embodiment of the inventive concepts, a semiconductor device includes a periphery circuit structure, and a cell structure on the periphery circuit structure, the cell structure including a cell region, a connection region, and a periphery circuit connection region, wherein the cell structure includes gate electrodes being apart from each other in the cell region in a vertical direction, a plurality of channel structures configured to penetrate the gate electrodes in the cell region to extend in the vertical direction, each of the plurality of channel structures including a first end portion and a second end portion, the first end portion being adjacent to the periphery circuit structure, the second end portion being opposite to the first end portion, a common source layer connected to the second end portion of each of the plurality of channel structures in the cell region, and a hydrogen rich layer between the common source layer and an uppermost one of the gate electrodes, and wherein a concentration of hydrogen (H) contained in the hydrogen rich layer is greater than a concentration of hydrogen (H) contained in the gate electrodes.

According to an example embodiment of the inventive concepts, a semiconductor device includes a substrate, a periphery circuit structure on the substrate, and a cell structure on the periphery circuit structure, the cell structure including a cell region, a connection region, and a periphery circuit connection region, wherein the cell structure includes gate electrodes being apart from each other in the cell region in a vertical direction, a hydrogen rich layer on the gate electrodes, a plurality of channel structures configured to penetrate the gate electrodes and the hydrogen rich layer in the cell region to extend in the vertical direction, each of the plurality of channel structures including a first end portion and a second end portion, the first end portion being adjacent to the periphery circuit structure, the second end portion being opposite to the first end portion, a common source layer connected to the second end portion of each of the plurality of channel structures, the common source layer covering an upper surface of the hydrogen rich layer in the cell region, and a conductive layer on an upper surface of the common source layer, and wherein a concentration of hydrogen (H) and/or deuterium (D) contained in the hydrogen rich layer is greater than a concentration of hydrogen (H) contained in the gate electrodes.

According to an example embodiment of the inventive concepts, a semiconductor device includes a periphery circuit structure, and a cell structure on the periphery circuit structure, the cell structure including a cell region, a connection region, and a periphery circuit connection region, wherein the cell structure includes gate electrodes being apart from each other in the cell region in a vertical direction, a hydrogen rich layer on an uppermost one of the gate electrodes, a channel structure configured to penetrate the gate electrodes and the hydrogen rich layer in the cell region to extend in the vertical direction, the channel structure including a first end portion and a second end portion, the first end portion being adjacent to the periphery circuit structure, the second end portion being opposite to the first end portion, a pad portion extending from the gate electrodes, the pad portion having a step shape in the connection region, an insulating wall extending at a boundary between the cell region and the connection region in the vertical direction, the insulating wall including an outer sidewall and an inner sidewall, a insulating base layer in the connection region and the periphery circuit connection region, the insulating base layer contacting the outer sidewall of the insulating wall, in the cell region, a common source layer in the cell region and connected to the second end portion of the channel structure and covering an upper surface of the hydrogen rich layer, and a conductive layer in the cell region and being conformal on the common source layer, and a first plug in the connection region and configured to penetrate the pad portion and extend in the vertical direction, a first end portion of the first plug penetrating the insulating base layer, and wherein a concentration of hydrogen (H) or deuterium (D) contained in the hydrogen rich layer is greater than a concentration of hydrogen (H) contained in the gate electrodes.

### BRIEF DESCRIPTION OF THE DRAWINGS

Example embodiments will be more clearly understood from the following detailed description taken in conjunction with the accompanying drawings in which:

FIG. 1 is a block diagram of a semiconductor device according to an example embodiment;

FIG. 2 is a circuit diagram of a memory block according to an example embodiment;

FIG. 3 is a perspective view of a representative configuration of a semiconductor device, according to an example embodiment;

FIG. 4 is a plan layout diagram of the semiconductor device in FIG. 3;

FIG. 5 is an enlarged layout diagram of region A in FIG. 4;

FIG. 6 is a cross-sectional view taken along line B1-B1′ and line B2-B2′ in FIG. 5;

FIG. 7 is an enlarged view of region CX1 in FIG. 6;

FIG. 8 is another enlarged view of region CX1 in FIG. 6;

FIGS. 9A through 9G are schematic diagrams illustrating a manufacturing method of a semiconductor device, according to an example embodiment;

FIG. 10 is a schematic diagram of a data storage system including a semiconductor device, according to an example embodiment;

FIG. 11 is a schematic perspective diagram of a data storage system including a semiconductor device, according to an example embodiment; and

FIG. 12 is a schematic cross-sectional view of a semiconductor package according to an example embodiment.

### DETAILED DESCRIPTION

Hereinafter, some example embodiments of the inventive concepts are described in detail with reference to accompanying diagrams. Identical reference numerals are used for the same constituent devices in the drawings, and duplicate descriptions thereof are omitted.

While the term “same,” “equal” or “identical” is used in description of example embodiments, it should be understood that some imprecisions may exist. Thus, when one element is referred to as being the same as another element, it should be understood that an element or a value is the same as another element within a desired manufacturing or operational tolerance range (e.g., ±10%).

When the term “about,” “substantially” or “approximately” is used in this specification in connection with a numerical value, it is intended that the associated numerical value includes a manufacturing or operational tolerance (e.g., ±10%) around the stated numerical value. Moreover, when the word “about,” “substantially” or “approximately” is used in connection with geometric shapes, it is intended that precision of the geometric shape is not required but that latitude for the shape is within the scope of the disclosure. Further, regardless of whether numerical values or shapes are modified as “about” or “substantially,” it will be understood that these values and shapes should be construed as including a manufacturing or operational tolerance (e.g., ±10%) around the stated numerical values or shapes.

As used herein, expressions such as “at least one of,” when preceding a list of elements, modify the entire list of elements and do not modify the individual elements of the list. Thus, for example, both “at least one of A, B, or C” and “at least one of A, B, and C” mean either A, B, C or any combination thereof. Likewise, A and/or B means A, B, or A and B.

Because various changes may be applied to the example embodiments and the inventive concepts may have various example embodiments, particular example embodiments are illustrated in the diagrams and described in detail. However, this is not intended to limit the inventive concepts to particular modes of practice, and it is to be appreciated that all changes, equivalents, and substitutes, which do not depart from the spirit and technical scope of the inventive concepts, are encompassed in the inventive concepts. In the description of the example embodiments, certain detailed explanations of the related art are omitted when it is deemed that they may unnecessarily obscure the essence of the example embodiments.

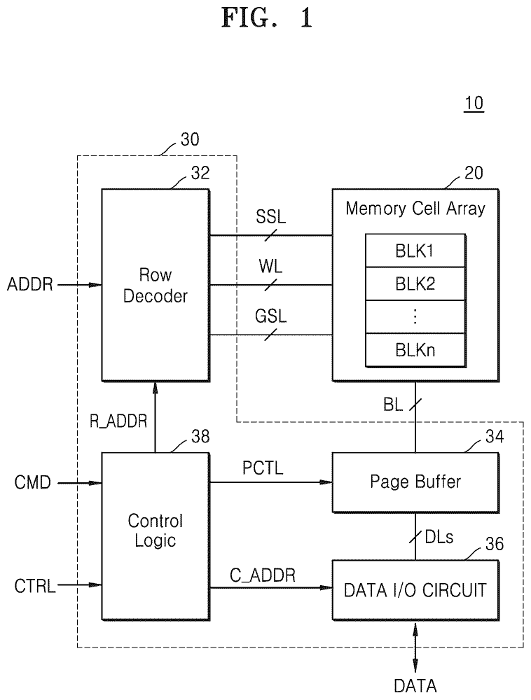

FIG. 1 is a block diagram of a semiconductor device 10 according to an example embodiment.

Referring to FIG. 1, the semiconductor device 10 may include a memory cell array 20 and a periphery circuit 30. The memory cell array 20 may include a plurality of memory cell blocks BLK1, BLK2, . . . , BLKn. Each of the plurality of memory cell blocks BLK1, BLK2, . . . , BLKn may include a plurality of memory cells. The plurality of memory cell blocks BLK1, BLK2, . . . , BLKn may be connected to the periphery circuit 30 via a bit line BL, a word line WL, a string selection line SSL, and a ground selection line GSL.

The periphery circuit 30 may include a row decoder 32, a page buffer 34, a data input/output (I/O) circuit 36, and a control logic 38. Although not illustrated in FIG. 1, the periphery circuit 30 may further include an I/O interface, a column logic, a voltage generator, a pre-decoder, a temperature sensor, a command decoder, an address decoder, an amplification circuit, etc.

The memory cell array 20 may be connected to the page buffer 34 via the bit line BL and may be connected to the row decoder 32 via the word line WL, the string selection line SSL, and the ground selection line GSL. In the memory cell array 20, each of the plurality of memory cells included in the plurality of memory cell blocks BLK1, BLK2, . . . , BLKn may include a flash memory cell. The memory cell array 20 may include a three-dimensional memory cell array. The three-dimensional memory cell array may include a plurality of NAND strings, and each NAND string may include a plurality of memory cells respectively connected to a plurality of word lines WL, which are vertically stacked on a substrate.

The periphery circuit 30 may receive an address ADDR, a command CMD, and a control signal CTRL from the outside of the semiconductor device 10 and may transceive data DATA to/from a device outside the semiconductor device 10.

The row decoder 32 may select at least one of the plurality of memory cell blocks BLK1, BLK2, . . . , BLKn in response to the address ADDR provided from the outside of the semiconductor device 10 and may select the word line WL, the string selection line SSL, and the ground selection line GSL of the selected at least one memory cell block. The row decoder 32 may transmit a voltage for performing a memory operation to the word line WL of the selected at least one memory cell block.

The page buffer 34 may be connected to the memory cell array 20 via the bit line BL. The page buffer 34 may operate as a write driver during a program operation to apply, to the bit line BL, a voltage according to the data DATA to be stored in the memory cell array 20, and as a sensing amplifier during a read operation to detect the data DATA stored in the memory cell array 20. The page buffer 34 may operate according to a control signal PCTL provided by the control logic 38.

The data I/O circuit 36 may be connected to the page buffer 34 via data lines DL. The data I/O circuit 36 may receive the data DATA from a memory controller (not illustrated) during the program operation and may provide the data DATA for a program operation to the page buffer 34 based on a column address C_ADDR provided by the control logic 38. The data I/O circuit 36 may provide, to the memory controller (not illustrated), the data DATA for a read operation stored in the page buffer 34 based on the column address C_ADDR provided by the control logic 38 during the read operation.

The data I/O circuit 36 may transmit an address or a command to be input thereto, to the control logic 38 or the row decoder 32. The periphery circuit 30 may further include an electrostatic discharge (ESD) circuit and a pull-up/pull-down driver.

The control logic 38 may receive the command CMD and the control signal CTRL from the memory controller. The control logic 38 may provide a row address R_ADDR to the row decoder 32 and the column address C_ADDR to the data I/O circuit 36. The control logic 38 may generate various internal control signals to be used by the semiconductor device 10, in response to the control signal CTRL. For example, the control logic 38 may control voltage levels to be provided to the word line WL and the bit line BL when memory operations, such as a program operation and an erase operation, are performed.

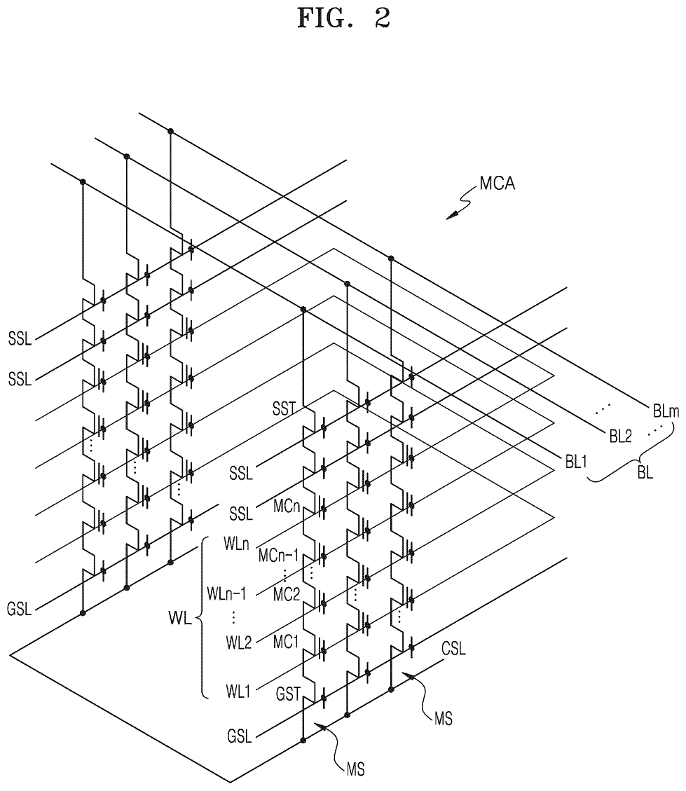

FIG. 2 is a circuit diagram of a memory cell block BLK according to an example embodiment.

Referring to FIG. 2, the memory cell array MCA may include a plurality of memory cell strings MS. The memory cell array MCA may include a plurality of bit lines BL (including BL1, BL2, . . . , BLm), a plurality of word lines WL (including WL1, WL2, . . . , WLn−1, WLn), at least one string selection line SSL, at least one ground selection line GSL, and a common source line CSL. The plurality of memory cell strings MS may be formed between the plurality of bit lines BL (including BL1, BL2, . . . , BLm) and the common source line CSL. In FIG. 2, the case is illustrated in which each of the plurality of memory cell strings MS includes two string selection lines SSL, but example embodiments are not limited thereto. For example, each of the plurality of memory cell strings MS may include one string selection line SSL.

Each of the plurality of memory cell strings MS may include a string selection transistor SST, a ground selection transistor GST, and a plurality of memory cell transistors MC1, MC2, . . . , MCn−1, MCn. A drain region of the string selection transistor SST may be connected to the plurality of bit lines BL (including BL1, BL2, . . . , BLm), and a source region of the ground selection transistor GST may be connected to the common source line CSL. The common source line CSL may include a region to which the source regions of a plurality of ground select transistors GST are connected in common.

The string selection transistor SST may be connected to the string selection line SSL, and the ground selection transistor GST may be connected to the ground selection line GSL. The plurality of memory cell transistors MC1, MC2, . . . , MCn−1, MCn may be connected to the plurality of word lines WL (including WL1, WL2, . . . , WLn−1, and WLn), respectively.

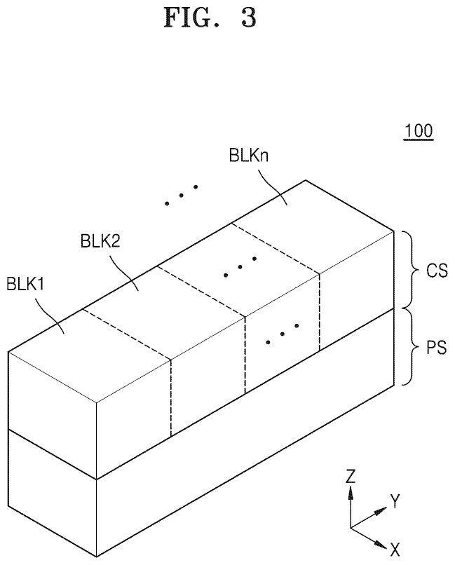

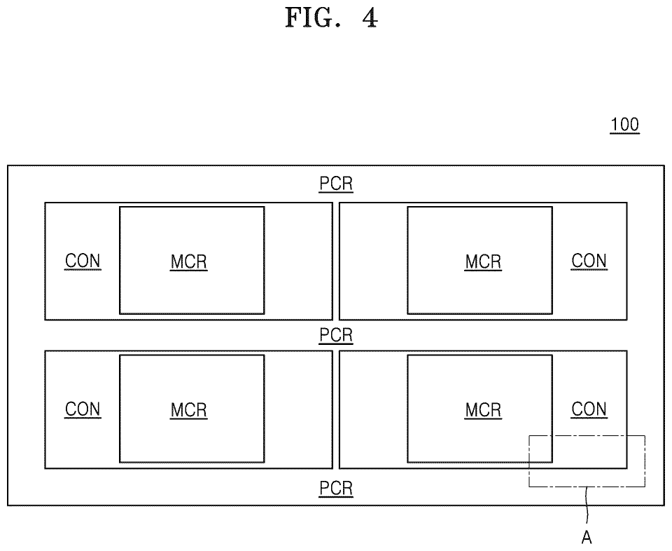

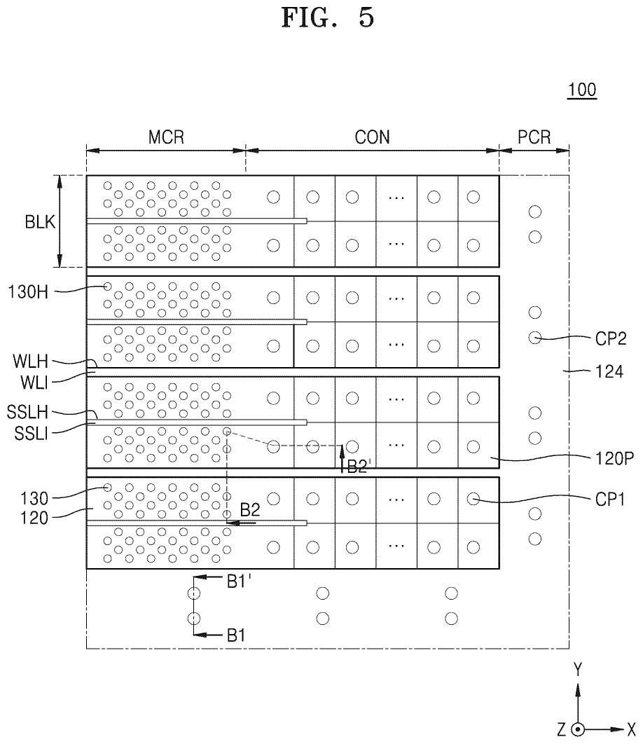

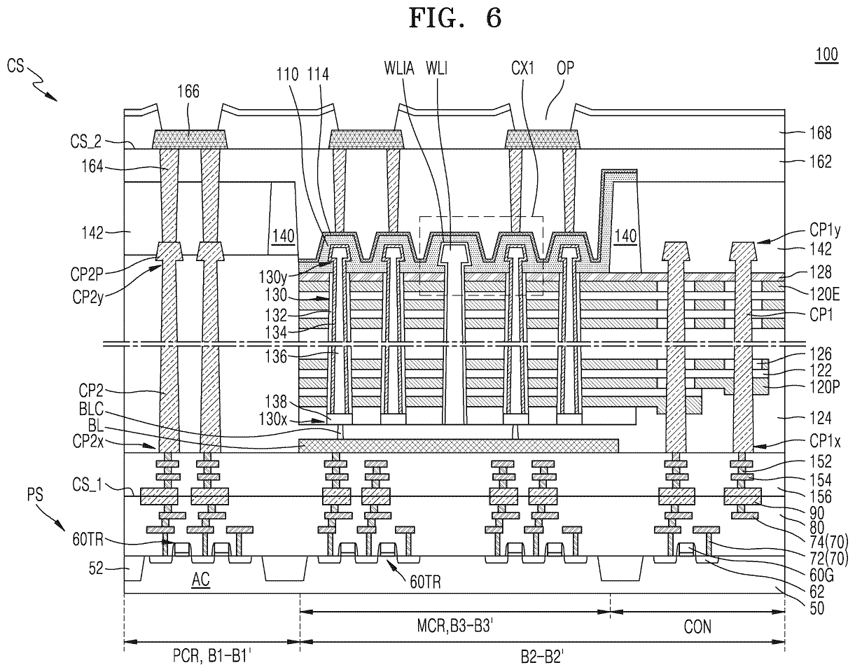

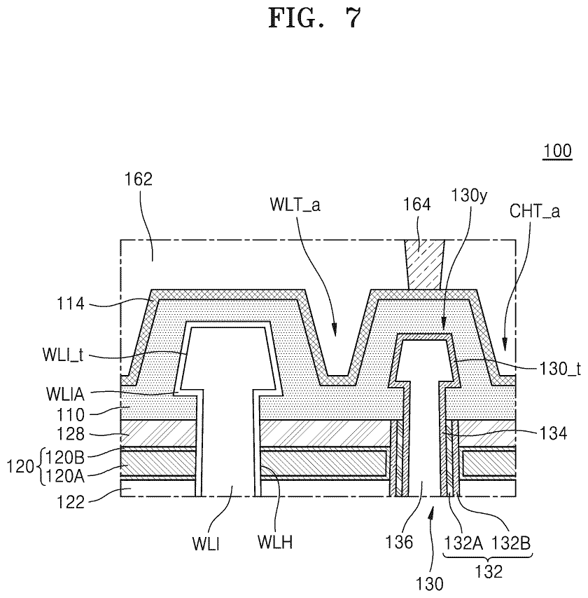

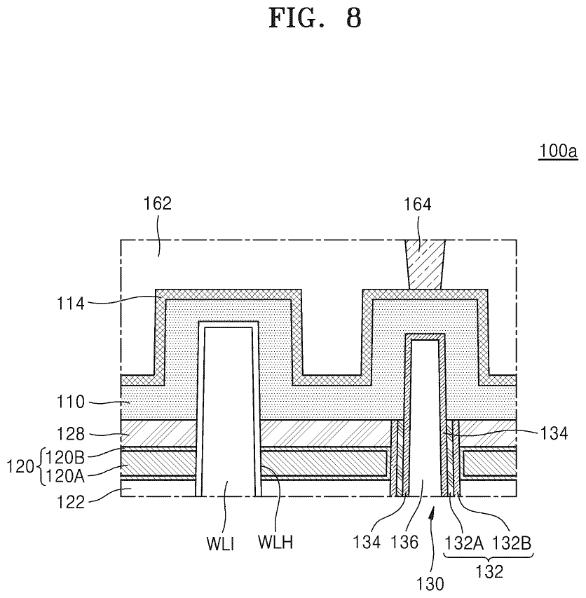

FIG. 3 is a perspective view of a representative configuration of a semiconductor device 100, according to an example embodiment. FIG. 4 is a plan layout of the semiconductor device 100, and FIG. 5 is an enlarged layout diagram of region A in FIG. 4. FIG. 6 is a cross-sectional view taken along line B1-B1′ and line B2-B2′ in FIG. 5. FIG. 7 is an enlarged view of region CX1 in FIG. 6, and FIG. 8 is another enlarged view of region CX1 in FIG. 6.

Referring to FIGS. 3 through 8, the semiconductor device 100 may include a cell structure CS and a periphery circuit structure PS, which overlap each other in a vertical direction (Z direction). The cell structure CS may include the memory cell array 20 described with reference to FIG. 1, and the periphery circuit structure PS may include the periphery circuit 30 described with reference to FIG. 1.

The cell structure CS may include the plurality of memory cell blocks BLK1, BLK2, . . . , BLKn. Each of the plurality of memory cell blocks BLK1, BLK2, . . . , BLKn may include memory cells, which are three-dimensionally arranged.

The periphery circuit structure PS may include a periphery circuit transistor 60TR and a periphery circuit distribution structure 70, which are arranged on a substrate 50. On the substrate 50, an active region AC may be defined by a device separation layer 52, and a plurality of periphery circuit transistors 60TR may be formed on the active region AC. The plurality of periphery circuit transistors 60TR may include periphery circuit gates 60G, and source/drain regions 62 arranged in portions of the substrate 50 on both sides of the periphery circuit gates 60G.

The substrate 50 may include a semiconductor material, for example, a Group IV semiconductor, a Group III-V compound semiconductor, or a Group II-VI oxide semiconductor. For example, the Group IV semiconductor may include silicon (Si), germanium (Ge), or silicon-germanium (SiGe). The substrate 50 may also be provided as a bulk wafer or an epitaxial layer. In another example embodiment, the substrate 50 may include a silicon-on-insulator (SOI) substrate or a germanium-on-insulator (GeOI) substrate.

The periphery circuit distribution structure 70 may include a plurality of periphery circuit contacts 72 and a plurality of periphery circuit distribution layers 74. On the substrate 50, a first interlayer insulating layer 80 covering the plurality of periphery circuit transistors 60TR and the periphery circuit distribution structure 70 may be arranged. The plurality of periphery circuit distribution layers 74 may have a multilayer structure including a plurality of metal layers arranged at different vertical levels. A connection pad 90 may be arranged on the first interlayer insulating layer 80, and the periphery circuit structure PS and the cell structure CS may be electrically connected and bonded to each other via the connection pad 90.

The cell structure CS may include a cell region MCR, a connection region CON, and a periphery circuit connection region PCR. The cell region MCR may be a region in which the memory cell block BLK including the plurality of memory cell strings MS extending in the vertical direction (Z direction) is arranged. In the cell region MCR, the common source layer 110, a plurality of gate electrodes 120, and a channel structure 130, which penetrates the plurality of gate electrodes 120, extends in the vertical direction (Z direction), and is connected to the common source layer 110, may be arranged. In the connection region CON, an extension portion 120E and a pad portion 120P, which are connected to the plurality of gate electrodes 120, and a first plug CP1, which penetrates the extension portion 120E and the pad portion 120P to be electrically connected to the pad portion 120P, may be arranged. In the periphery circuit connection region PCR, a second plug CP2, which extends in the vertical direction (Z direction) and is electrically connected to the periphery circuit distribution structure 70, may be arranged.

The cell structure CS may include a first surface CS_1 connected to the periphery circuit structure PS and a second surface CS_2 opposite to the first surface CS_1. FIG. 6 illustrates that the first surface CS_1 of the cell structure CS is arranged on the lower side of the cell structure CS and the second surface CS_2 of the cell structure CS is arranged on the upper side of the cell structure CS. In this case, for convenience, as illustrated in FIG. 6, an arrangement close to the first surface CS_1 of the cell structure CS may be referred to as an arrangement at a lower vertical level and an arrangement close to the second surface CS_2 of the cell structure CS may be referred to as an arrangement at a higher vertical level.

As illustrated in FIGS. 7 and 8 as an example, the gate electrode 120 may include a buried conductive layer 120A and a conductive barrier layer 120B surrounding a top surface, a bottom surface, and side surfaces of the buried conductive layer 120A. For example, the buried conductive layer 120A may include metal, such as tungsten, nickel, cobalt, and tantalum, metal silicide, such as tungsten silicide, nickel silicide, cobalt silicide, and tantalum silicide, and polysilicon doped with impurities, or a combination thereof. In some example embodiments, the conductive barrier layer 120B may include titanium nitride, tantalum nitride, tungsten nitride, or a combination thereof.

In some example embodiments, a hydrogen rich layer 128 may be deposited on the gate electrode 120 arranged at the closest vertical level to the second surface CS_2 of the cell structure CS among the gate electrodes 120. In some example embodiments, the thickness of the hydrogen rich layer 128 may be in a range of about 50 Å to about 500 Å, but inventive concepts are not limited thereto.

In some example embodiments, the concentration of hydrogen (H) contained in the hydrogen rich layer 128 may be higher than the concentration of hydrogen (H) contained in a mold insulating layer 122. For example, the concentration of hydrogen (H) contained in the hydrogen rich layer 128 may be about 1% or more higher than the concentration of hydrogen (H) contained in the mold insulating layer 122. In some example embodiments, the concentration of hydrogen (H) contained in the hydrogen rich layer 128 may also be about 20% or more higher than the concentration of hydrogen (H) contained in the mold insulating layer 122.

In some example embodiments, the hydrogen rich layer 128 may contain deuterium (D) instead of hydrogen (H). In some example embodiments, the concentration of deuterium (D) contained in the hydrogen rich layer 128 may be higher than the concentration of hydrogen (H) contained in the mold insulating layer 122. For example, the concentration of deuterium (D) contained in the hydrogen rich layer 128 may be about 1% or more higher than the concentration of hydrogen (H) contained in the mold insulating layer 122. In some example embodiments, the concentration of deuterium (D) contained in the hydrogen rich layer 128 may also be about 20% or more higher than the concentration of hydrogen (H) contained in the mold insulating layer 122.

However, the inventive concepts are not limited thereto, and the hydrogen rich layer 128 may also contain both hydrogen (H) and deuterium (D). Even in this case, the concentration of hydrogen (H) and/or deuterium (D) contained in the hydrogen rich layer 128 may be higher than the concentration of hydrogen (H) contained in the mold insulating layer 122.

In addition, in some example embodiments, the hydrogen rich layer 128 may include silicon nitride (SiN).

In some example embodiments, the gate electrodes 120 may correspond to the ground selection line (refer to GSL in FIG. 2), the plurality of word lines (refer to WL (including WL1, WL2, . . . , WLn−1, and WLn) in FIG. 2), and at least one string selection line (refer to SSL in FIG. 2), which constitute the memory cell string (refer to MS in FIG. 2). For example, the uppermost one of the gate electrodes 120 may function as the ground selection line GSL, the lowermost two of the gate electrodes 120 may function as the string selection line SSL, and the other gate electrodes 120 may function as the word line WL. Accordingly, the memory cell string MS, in which the ground selection transistor GST, the plurality of memory cell transistors MC1, MC2, . . . , MCn−1, and MCn, and the string selection transistor SST are connected in series, may be provided. In some example embodiments, at least one of the gate electrodes 120 may also function as a dummy word line, but inventive concepts are not limited thereto.

A stack separation insulating layer WLI may be arranged in a stack separation opening WLH, which penetrates the gate electrodes 120 and the mold insulating layers 122 and extends in the vertical direction (Z direction). The upper surface of the stack separation insulating layer WLI may be at a higher vertical level than the uppermost gate electrode 120 and the hydrogen rich layer 128, and may protrude upward with reference to the uppermost gate electrode 120 and the hydrogen rich layer 128. As illustrated in FIG. 5, the gate electrode 120 arranged between a pair of stack separation openings WLH may constitute one memory cell block BLK. In addition, in one memory cell block BLK, at least one gate electrode 120 (e.g., the lowermost gate electrode 120) may be separated into two gate electrodes 120 by a string separation opening SSLH. A string separation insulating layer SSLI may be arranged in the string separation opening SSLH.

A stack insulating layer 124 may be arranged to surround the gate electrodes 120, the extension portions 120E, and the pad portions 120P in the connection region CON and the periphery circuit connection region PCR. In a plan view, the stack insulating layer 124 may be arranged to surround the gate electrodes 120 and may have an upper surface at the same level as the uppermost gate electrode 120 in the periphery circuit connection region PCR.

The channel structure 130 may include a first end portion 130x arranged close to the periphery circuit structure PS, and a second end portion 130y opposite to the first end portion 130x. In some example embodiments, the channel structure 130 may have a sidewall inclined such that a width of the first end portion 130x is greater than a width of the second end portion 130y. The bit line BL may be electrically connected to the first end portion 130x of the channel structure 130 via a bit line contact BLC, and the common source layer 110 may be connected to the second end portion 130y of the channel structure 130.

The channel structure 130 may be arranged in a channel hole 130H, which penetrates the gate electrodes 120, the mold insulating layers 122, and the hydrogen rich layer 128 and extends in a vertical direction, and may include a gate insulating layer 132, a channel layer 134, a buried insulating layer 136, and a drain region 138. The channel layer 134 may have a cylindrical shape, the gate insulating layer 132 may be arranged on an outer wall of the channel layer 134, and the buried insulating layer 136 may be arranged on an inner wall of the channel layer 134. The gate insulating layer 132 may not be arranged on the uppermost surface of the channel layer 134 (e.g., on an upper surface of the channel layer 134 arranged at the second end portion 130y of the channel structure 130).

As illustrated in FIGS. 7 and 8, the gate insulating layer 132 may have a structure in which a charge storage layer 132A and a blocking dielectric layer 132B are sequentially arranged on the outer wall of the channel layer 134. Relative thicknesses of the charge storage layer 132A and the blocking dielectric layer 132B, which constitute the gate insulating layer 132, are not limited to those illustrated in FIG. 8 and may be variously modified.

According to an example embodiment, the charge storage layer 132A may include a ferroelectric material. For example, the charge storage layer 132A may include at least one of HfO₂, Hf₁₋ₓZrₓO₂ (0<x≤0.5), Ba₁₋ₓSrₓTiO₃ (0≤x≤0.3), BaTiO₃, or PbZrₓTi₁₋ₓO₃ (0≤x≤0.1). In addition, the charge storage layer 132A may further include impurities, and the impurities may include aluminum (Al), titanium (Ti), tantalum (Ta), niobium (Nb), lanthanum (La), yttrium (Y), magnesium (Mg), silicon (Si), calcium (Ca), cerium (Ce), dysprosium (Dy), avium (Er), gadolinium (Gd), germanium (Ge), scandium (Sc), strontium (Sr), tin (Sn), etc.

The blocking dielectric layer 132B may include silicon oxide, silicon nitride, or metal oxide having a higher dielectric constant than silicon oxide. The metal oxide may include hafnium oxide, aluminum oxide, zirconium oxide, Ta oxide, or a combination thereof.

The common source layer 110 may be formed on the hydrogen rich layer 128 to be connected to the second end portion 130y of the channel structure 130. In other words, the hydrogen rich layer 128 may be arranged between the uppermost gate electrode 120 and the common source layer 110. In a plan view, the common source layer 110 may be arranged on the entire region of the cell region MCR.

Referring to FIG. 7, the common source layer 110 may include a stack separation trench WLT_a and a plurality of channel trenches CHT_a. The stack separation trench WLT_a may be formed by extending in a first horizontal direction (X direction) and may not overlap the stack separation insulating layer WLI in the vertical direction (Z direction). In some example embodiments, the common source layer 110 may be formed to conformally surround an upper surface of the hydrogen rich layer 128, an upper end portion WLI_t of the stack separation insulating layer WLI, and an upper end portion 130_t of the channel structure 130.

In the semiconductor device 100 of FIG. 7, the upper end portion WLI_t of the stack separation insulating layer WLI may have a greater width in a lateral direction (e.g., an X direction or a Y direction) than a lower end portion of the stack separation insulating layer WLI. The upper end portion WLI_t of the stack separation insulating layer WLI may have a trapezoidal cross-section in which the width thereof in the lateral direction (e.g., the X direction or the Y direction) increases toward the periphery circuit structure PS in the vertical direction (Z direction). The upper end portion WLI_t of the stack separation insulating layer WLI may be arranged between the stack separation trenches WLT_a. The portions of the stack separation insulating layer WLI, which are not exposed in the stack separation trench WLT_a and buried in the stacked mold insulating layers 122 and the gate electrodes 120, may have a width less than the upper end portion WLI_t in the lateral direction (e.g., the X direction or the Y direction).

According to the example embodiment, the plurality of channel trenches CHT_a may be apart from each other in the second horizontal direction (Y direction) with the stack separation trench WLT_a therebetween.

According to the example embodiment, the upper end portion 130_t of the channel structure 130 may have a width greater than a width of the lower end portion of the channel layer 134 in the lateral direction (e.g., the X direction or the Y direction). The upper end portion 130_t of the channel structure 130 may have a trapezoidal cross-section, in which the width in the lateral direction (e.g., the X direction or the Y direction) increases in a downward direction of the vertical direction (e.g., Z direction), that is, toward the periphery circuit structure PS. Some upper end portions 130_t of the plurality of channel structures 130 may overlap the channel trench CHT_a in the vertical direction (e.g., Z direction), and may be buried in the common source layer 110.

The stack separation trench WLT_a and the channel trench CHT_a may have a tapered shape in which the widths thereof in the lateral direction (e.g., the X direction or the Y direction) decrease in a downward direction in the vertical direction (e.g., Z direction), that is, toward the periphery circuit structure PS. The stack separation trench WLT_a and the channel trench CHT_a may be defined by etching a conductive layer 114 and the common source layer 110. According to the example embodiment, a common source layer 110 may overlap and contact the channel layer 134 of a cylindrical shape arranged at the second end portion 130y of the channel structure 130 in the vertical direction (Z direction).

In some example embodiments, the semiconductor device 100 may further include a conductive layer 114 arranged to be in contact with an upper surface of the common source layer 110. The conductive layer 114 may be deposited to conformally cover or surround the upper surface of the common source layer 110 with a certain thickness. A lower surface of the conductive layer 114 may be coplanar with the upper surface of the common source layer 110. On the sidewall of the upper end portion 130_t of the channel structure 130 and the sidewall of the upper end portion WLI_t of the stack separation insulating layer WLI, the sidewall of the conductive layer 114 may be inclined to be away from the center of the channel structure 130 downward in the vertical direction (Z direction). Likewise, the sidewall of the common source layer 110 may also be inclined to be away from the center of the channel structure 130 downward in the vertical direction (Z direction). The conductive layer 114 may include titanium nitride, tantalum nitride, tungsten nitride, or a combination thereof. For example, the conductive layer 114 may include metal, such as tungsten, molybdenum, chromium, nickel, cobalt, and tantalum, a metal silicide, such as tungsten silicide, nickel silicide, cobalt silicide, and tantalum silicide, or a combination thereof.

According to the example embodiment, the stack separation trench WLT_a and the channel trench CHT_a may be filled with an upper interlayer insulating layer 162 to be described below. In addition, as to be described in detail below, a rear surface pad 166 may be arranged on the upper interlayer insulating layer 162, and a rear surface via 164 may be formed to penetrate the upper interlayer insulating layer 162. The rear surface via 164 may penetrate the upper interlayer insulating layer 162 to be connected to the rear surface pad 166 and the conductive layer 114. The rear surface via 164 may perform a role of the common source line CSL illustrated in FIG. 2.

FIG. 8 is another enlarged view of region CX1 in FIG. 6. A semiconductor device 100a of FIG. 8 is similar to the semiconductor device 100 of FIG. 7 except that an upper end portion of the channel structure 130 and an upper end portion of the stack separation insulating layer WLI have different shapes compared to those of the semiconductor device 100 of FIG. 7. Thus, duplicate descriptions thereof are omitted below, and the differences thereof are mainly described. The same reference numbers as those in FIG. 7 may represent the same components.

Referring to FIG. 8, the stack separation insulating layer WLI may have a pillar structure partially protruding in the vertical direction (Z direction) with respect to the hydrogen rich layer 128. The sidewalls of the stack separation insulating layer WLI may extend in parallel with each other in the vertical direction (Z direction). In some example embodiments, the channel structure 130 may have a column structure partially protruding in the vertical direction (Z direction) with respect to the hydrogen rich layer 128. In some example embodiments, the channel layer 134 may extend along the side and top surfaces of the channel structure 130. In some example embodiments, the charge storage layer 132A and the blocking dielectric layer 132B, which are sequentially deposited on the outer wall of the channel layer 134, may not extend outside the hydrogen rich layer 128. In other words, the uppermost surfaces of the charge storage layer 132A and the blocking dielectric layer 132B may be arranged at a vertical level lower than a vertical level of the common source layer 110.

Referring to FIG. 6 again, an insulating wall 140 may be arranged at a boundary between the cell region MCR and the connection region CON. The insulating wall 140 may be arranged to surround the cell region MCR in a plan view and may have an upper surface at a vertical level higher than the vertical level of the hydrogen rich layer 128. The insulating wall 140 may be formed to have a relatively large height. In some example embodiments, the insulating wall 140 may include silicon oxide, silicon nitride, silicon oxynitride (SiON), silicon oxycarbide nitride (SiOCN), silicon carbide nitride (SiCN), or a combination thereof.

An insulating base layer 142 may be arranged in the connection region CON and the periphery circuit connection region PCR. The insulating base layer 142 may be formed to have the same height as the insulating wall 140. The insulating base layer 142 may be arranged to surround the insulating wall 140 in a plan view, and the outer side wall of the insulating wall 140 may be in contact with the insulating base layer 142. In some example embodiments, the insulating base layer 142 may include silicon oxide, silicon nitride, SiON, SiOCN, SiCN, or a combination thereof.

In the connection region CON, a first plug CP1 may be arranged to penetrate an extension portion 120E and a pad portion 120P, which extend from the gate electrode 120. Insulating patterns 126 may be formed at a position vertically overlapping the pad portion 120P connected to the first plug CP1, and the insulating patterns 126 may be arranged between the first plug CP1 and extension portions 120E.

In the example embodiment, a first end portion CP1x of the first plug CP1 may be arranged at a position adjacent to the periphery circuit structure PS, and a second end portion CP1y of the first plug CP1 may be arranged opposite to the first end portion CP1x. The first plug CP1 may have a sidewall inclined such that the width of the first end portion CP1x is greater than the width of the second end portion CP1y. The second end portion CP1y of the first plug CP1 may penetrate the insulating base layer 142 and extend in a direction perpendicular to the substrate 50, and an upper surface of the second end portion CP1y of the first plug CP1 may be covered by the insulating base layer 142.

In the periphery circuit connection region PCR, the second plug CP2 may be arranged to penetrate the stack insulating layer 124. A first end portion CP2x of the second plug CP2 may be arranged at a location adjacent to the periphery circuit structure PS, and a second end portion CP2y of the second plug CP2 may be arranged opposite to the first end portion CP2x. The second plug CP2 may have a sidewall inclined such that the width of the first end portion CP2x is greater than the width of the second end portion CP2y. The second end portion CP1y of the second plug CP2 may be in contact with a landing pad CP2P, and at least a portion of the landing pad CP2P may be covered by the insulating base layer 142.

Between the stack insulating layer 124 and the periphery circuit structure PS, a connection via 152, a connection distribution layer 154, and a second interlayer insulating layer 156 surrounding the connection via 152 and the connection distribution layer 154 may be arranged. The connection via 152 and the connection distribution layer 154 may be configured in multiple layers at a plurality of vertical levels, and the bit line BL, the first plug CP1, and the second plug CP2 may be electrically connected to the periphery circuit structure PS via the connection pad 90.

The upper interlayer insulating layer 162 may be arranged on the common source layer 110 and the conductive layer 114, rear surface vias 164 may be arranged through the upper interlayer insulating layer 162, and rear surface pads 166 may be arranged on the upper interlayer insulating layer 162. At least one of the rear surface vias 164 may penetrate the upper interlayer insulating layer 162 in the cell region MCR and be arranged to be connected to the upper surface of the conductive layer 114, and at least one other of the rear surface vias 164 may penetrate the upper interlayer insulating layer 162 and the insulating base layer 142 in the periphery circuit connection region PCR, extend into the insulating base layer 142, and be connected to the landing pad CP2P. The rear surface pads 166 may be connected to the rear surface vias 164. A passivation layer 168 may be arranged on the upper interlayer insulating layer 162, and an opening OP of the passivation layer 168 may expose the upper surfaces of the rear surface pads 166. Although FIG. 6 illustrates that the rear surface pad 166 is connected to at least two rear surface vias 164 in the lateral direction, the inventive concepts are not limited thereto, and the rear surface pad 166 may also be connected to one rear surface via 164 or may also be connected to three or more rear surface vias 164.

In the semiconductor devices 100 and 100a according to present example embodiments, by performing a process of depositing an oxide material containing a relatively large amount of hydrogen (H) and/or deuterium (D) or the hydrogen rich layer containing silicon oxide material before forming a mold region on a carrier substrate, hydrogen (H) and/or deuterium (D) may be effectively supplied to a channel hole when a high temperature process of forming a cell region proceeds. Thus, an issue of supply deficiency of hydrogen (H) and/or deuterium (D), which may occur according to an increase in the number of layers of a semiconductor device, may be improved, and operation reliability of the semiconductor device may be improved.

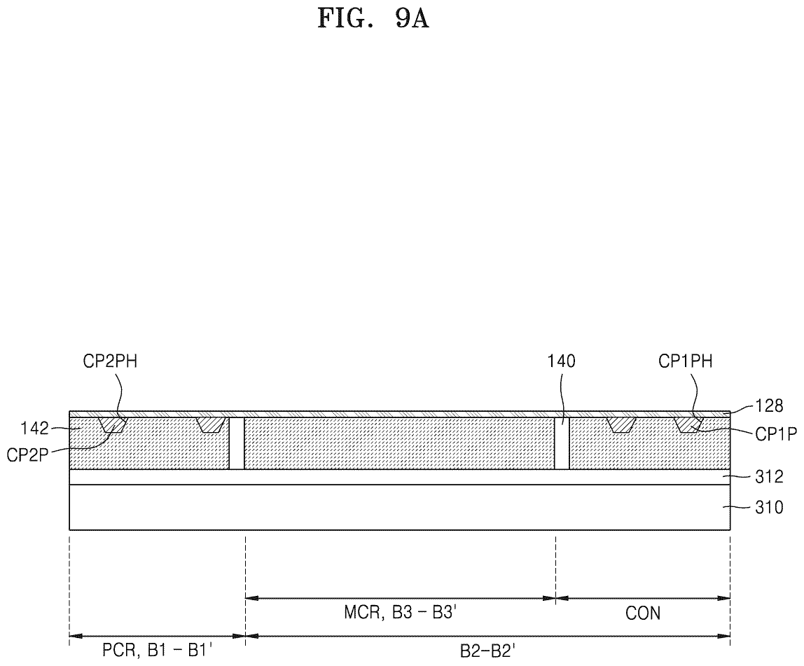

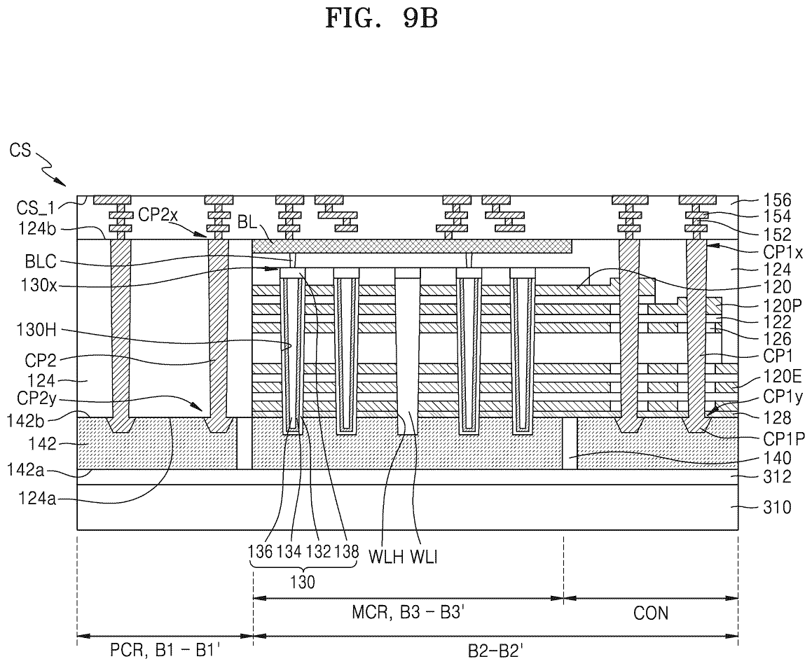

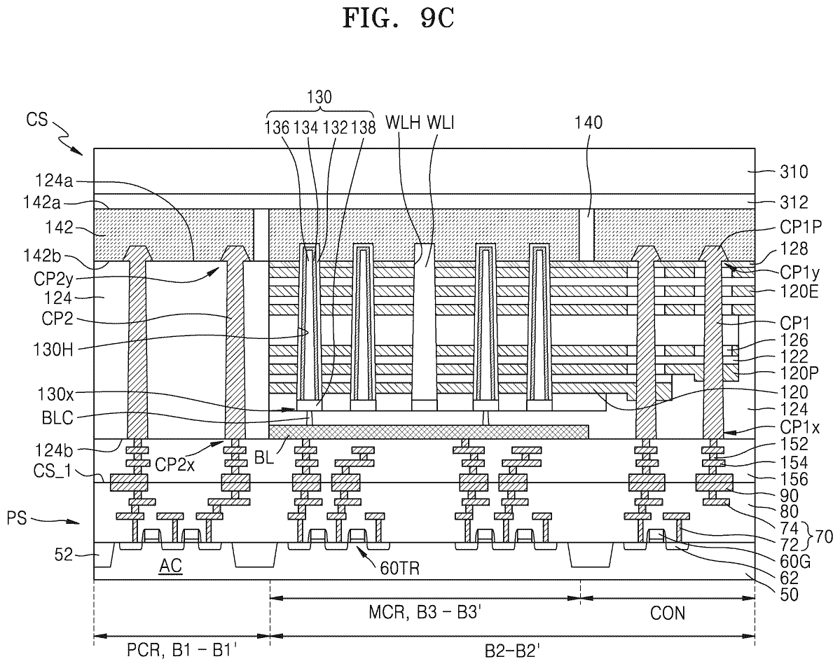

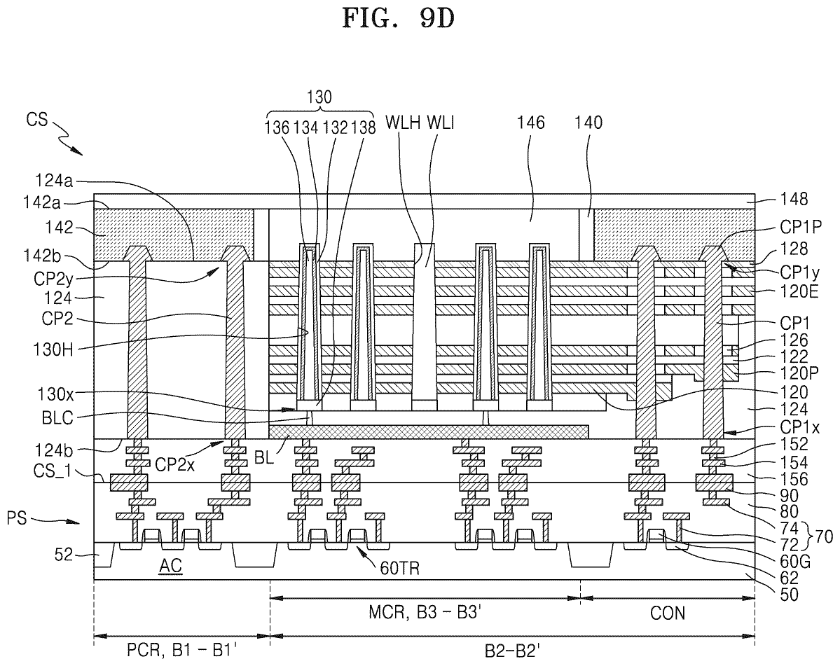

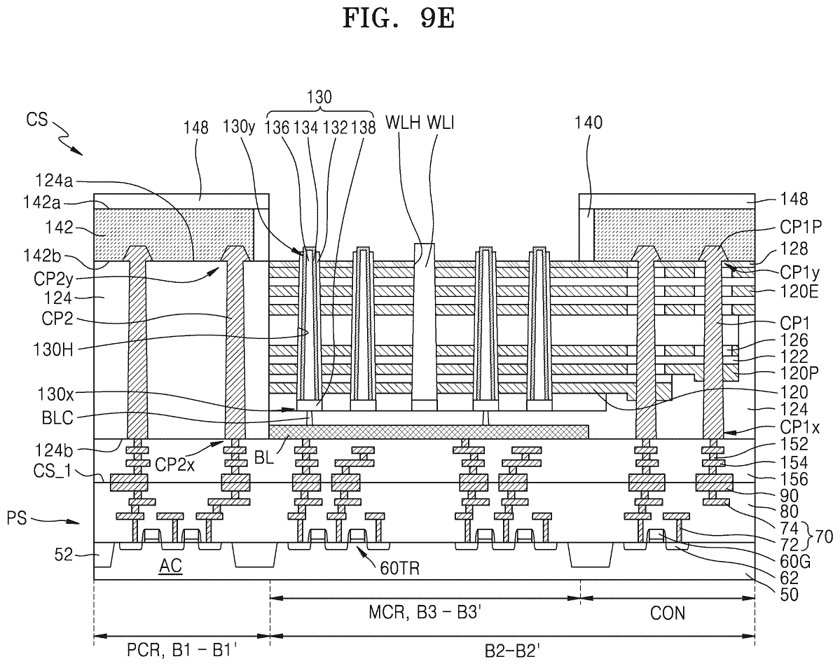

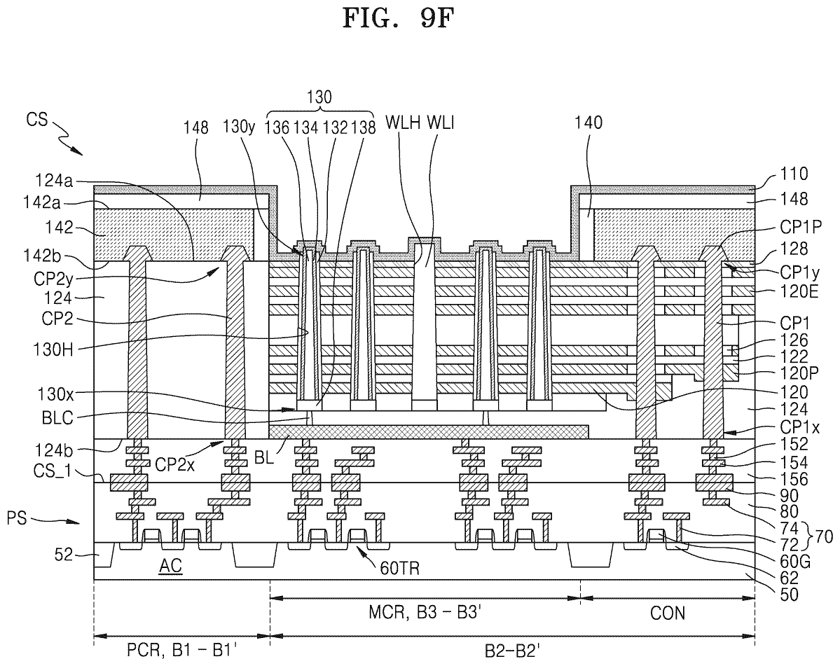

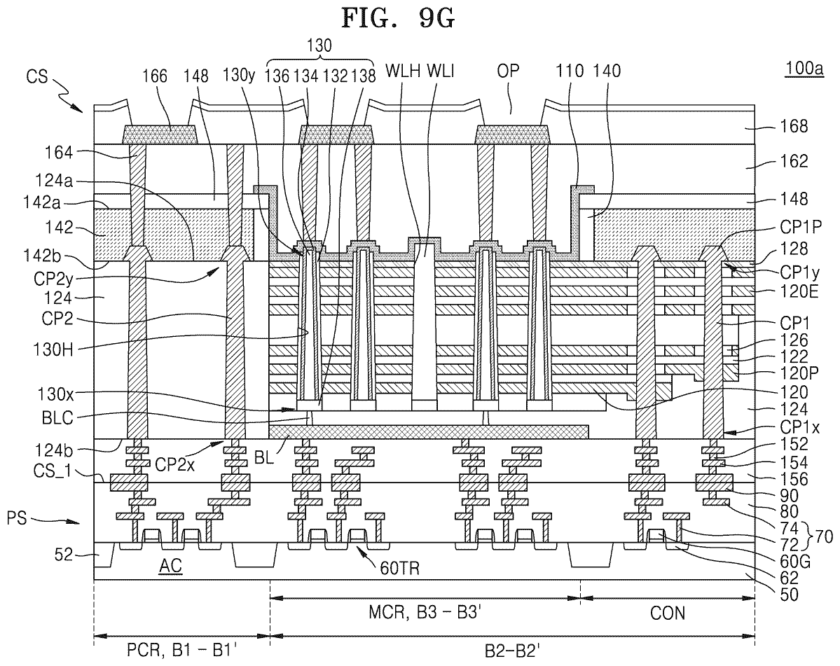

FIGS. 9A through 9G are schematic diagrams illustrating a manufacturing method of a semiconductor device, according to an example embodiment. FIGS. 9A through 9G may be cross-sectional views illustrating a method of manufacturing the semiconductor device 100a illustrated in FIG. 8.

Referring to FIG. 9A, firstly, a buffer insulating layer 312 may be formed on a carrier substrate 310, and an insulating base layer 142 may be formed on the buffer insulating layer 312.

In some example embodiments, the carrier substrate 310 may include Si, Ge, SiGe, gallium arsenide (GaAs), indium gallium arsenide (InGaAs), aluminum gallium arsenide (AlGaAs), or a combination thereof. The buffer insulating layer 312 may be formed by using a combination of silicon oxide, a double layer of silicon oxide and titanium nitride, a double layer of silicon oxide and silicon nitride, etc.

In the carrier substrate 310, the cell region MCR, the connection region CON, and the periphery circuit connection region PCR may be defined, and the insulating base layer 142 may be formed to have a uniform height entirely over the cell region MCR, the connection region CON, and the periphery circuit connection region PCR.

The insulating wall 140 may be formed by removing a portion of the insulating base layer 142. The insulating wall 140 may be formed at a boundary between the cell region MCR and the connection region CON, at a boundary between the cell region MCR and the periphery circuit connection region PCR, and/or at a boundary between the connection region CON and the periphery circuit connection region PCR.

In the connection region CON, a portion of the insulating base layer 142 may be removed to form a first landing pad opening CP1PH, and a first landing pad CP1P may be formed in the first landing pad opening CP1PH. In the periphery circuit connection region PCR, a portion of the insulating base layer 142 may be removed to form a second landing pad opening CP2PH, and a second landing pad CP2P may be formed in the second landing pad opening CP2PH.

Thereafter, the hydrogen rich layer 128 may be formed on the insulating base layer 142. In some example embodiments, the hydrogen rich layer 128 may be formed to have a concentration higher than a concentration of hydrogen (H) contained in the mold insulating layer 122 that is to be deposited with hydrogen (H) and/or deuterium (D) later. In some example embodiments, the hydrogen rich layer 128 may include silicon nitride.

Referring to FIG. 9B, the gate electrodes 120 and the mold insulating layers 122 may be formed in the cell region MCR and the connection region CON, and the extension portions 120E and the pad portions 120P connected to the gate electrodes 120 may be formed in the connection region CON. In addition, the channel structure 130 penetrating the gate electrodes 120 and extending in the vertical direction (Z direction), and the bit line BL connected to the channel structure 130 may be formed in the cell region MCR. In addition, referring to FIGS. 5 and 8 together, the stack separation opening WLH extending from the cell region MCR to the connection region CON in the first horizontal direction (X direction) may be formed. The stack separation insulating layer WLI may be formed in the stack separation opening WLH.

The first plug CP1 penetrating the extension portions 120E and the pad portions 120P may be formed in the connection region CON, and the second plug CP2 penetrating the stack insulating layer 124 may be formed in the periphery circuit connection region PCR. In addition, the connection via 152, the connection distribution layer 154, and the second interlayer insulating layer 156 electrically connected to the bit line BL, the first plug CP1, and the second plug CP2 may be formed.

In some example embodiments, in the process for forming the channel structure 130, the first end portion 130x of the channel structure 130 may be arranged at a higher vertical level than the second end portion 130y. The second end portion 130y of the channel structure 130 may be formed to penetrate the hydrogen rich layer 128 and extend into the insulating base layer 142. For example, when viewed in an upside-down direction, the second end portion 130y of the channel structure 130 may be arranged at a vertical level lower than an upper surface 142a of the insulating base layer 142.

In some example embodiments, in the process of forming the first plug CP1, the first end portion CP1x of the first plug CP1 may be formed to have a larger width than the second end portion CP1y. The second end portion CP1y of the first plug CP1 may be connected to the first landing pad CP1P.

In some example embodiments, in the process of forming the second plug CP2, the first end portion CP2x of the second plug CP2 may be formed to have a larger width than the second end portion CP2y. The second end portion CP2y of the second plug CP2 may be connected to the second landing pad CP2P.

The connection via 152, the connection distribution layer 154, and the second interlayer insulating layer 156 surrounding the connection via 152 and the connection distribution layer 154 may be formed on the stack insulating layer 124.

Referring to FIG. 9C, the periphery circuit structure PS may be prepared. The periphery circuit structure PS may include a periphery circuit transistor 60TR and a periphery circuit distribution structure 70. On a substrate 50, the active region AC may be defined by an element separation layer 52, and a plurality of periphery circuit transistors 60TR may be formed in the active region AC. The plurality of periphery circuit transistors 60TR may include periphery circuit gates 60G, and source/drain regions 62 arranged on both sides of the periphery circuit gates 60G in portions of the substrate 50.

Thereafter, the periphery circuit structure PS may be attached to the cell structure CS. The periphery circuit structure PS and the cell structure CS may be attached to each other by using a metal-oxide hybrid bonding method via the connection pad 90 and the first and second interlayer insulating layers 80 and 156, but example embodiments are not limited thereto.

Thereafter, a structure, to which the periphery circuit structure PS and the cell structure CS are attached, may be inverted so that the carrier substrate 310 faces upward.

Referring to FIG. 9D, the carrier substrate 310 (refer to FIG. 9C) may be removed. The carrier substrate 310 may be removed by using a grinding process and a subsequent etching process, and the buffer insulating layer 312 (refer to FIG. 9C) may be exposed.

Thereafter, the buffer insulating layer 312 (refer to FIG. 9C) may also be removed, and the upper surface 142a of the insulating base layer 142 and an upper surface of the insulating wall 140 may be exposed. In this case, the upper surface 142a of the insulating base layer 142 may indicate a surface of the insulating base layer 142 that has been in contact with the buffer insulating layer 312, and a lower surface 142b of the insulating base layer 142 may indicate a surface of the insulating base layer 142 that is arranged adjacent to the channel structure 130.

In the periphery circuit connection region PCR and the connection region CON, a mask pattern (not illustrated) may be formed on the insulating base layer 142. The mask pattern may expose the upper surface 142a of the insulating base layer 142 in the cell region MCR. When an etching process is performed by using the mask pattern as an etching mask, the insulating base layer 142 arranged in the cell region MCR may be removed. As the insulating base layer 142 is removed, a portion of the channel structure 130, a portion of the stack separation insulating layer WLI may be exposed.

Next, an upper insulating layer 146, which covers the upper portion of the exposed channel structure 130 and the upper portion of the stack separation insulating layer WLI may be formed. The upper insulating layer 146 may include a silicon oxide layer, a silicon nitride layer, SiON, SiOCN, SiCN, or a combination thereof.

Next, a cover insulating layer 148 may be formed on the upper insulating layer 146. The cover insulating layer 148 may include a silicon oxide layer, a silicon nitride layer, SiON, SiOCN, SiCN, or a combination thereof.

Referring to FIG. 9E, an etching process may be performed on the upper insulating layer 146 and the cover insulating layer 148 in FIG. 9D. Portions of the upper insulating layer 146 and the cover insulating layer 148 may be removed by using the etching process operation.

As portions of the upper insulating layer 146 and the cover insulating layer 148 are removed, the second end portion 130y of the channel structure 130 may be exposed.

Thereafter, the upper surface of the channel layer 134 may be exposed by removing the portion of the gate insulating layer 132 exposed to the second end portion 130y of the channel structure 130. In the process of removing the gate insulating layer 132, the process of removing the gate insulating layer 132 may be performed so the upper surface of the hydrogen rich layer 128 is exposed. In some example embodiments, the upper side of the gate insulating layer 132 may be further removed such that the gate insulating layer 132 is arranged at a lower level than the upper surface of the channel layer 134 and portions of the upper surface and the sidewall of the channel layer 134 are exposed.

On the other hand, in the process of removing the gate insulating layer 132, the upper side of the stack separation insulating layer WLI may also be exposed to protrude above the upper side of the hydrogen rich layer 128.

Referring to FIG. 9F, the common source layer 110 may be formed on the cell region MCR, the connection region CON, and the periphery circuit connection region PCR. The common source layer 110 may include polysilicon. For example, the common source layer 110 may include polysilicon doped with n-type impurities. For example, the common source layer 110 may include polysilicon doped with p-type impurities. In some example embodiments, the common source layer 110 may also have a composite structure of polysilicon doped with n-type impurities and polysilicon doped with p-type impurities.

In the cell region MCR, the common source layer 110 may be conformally formed on the exposed upper surfaces of the hydrogen rich layer 128 and the channel layer 134. The common source layer 110 may extend onto a cover insulating layer 148. Although not illustrated, a conformal conductive layer (refer to 114 in FIG. 8) may be additionally deposited on the upper surface of the common source layer 110.

Referring to FIG. 9G, a portion of the common source layer 110 arranged in the connection region CON and the periphery circuit connection region PCR may be partially removed. The conductive layer (refer to 114 in FIG. 8) deposited on the common source layer 110, which is removed in the process described above, may also be removed.

Next, the upper interlayer insulating layer 162 may be formed on the common source layer 110 and the cover insulating layer 148. Thereafter, in the periphery circuit connection region PCR, the rear surface via 164 penetrating the upper interlayer insulating layer 162 and the cover insulating layer 148 may be formed. The rear surface via 164 may be connected to the second landing pad CP2P. In the cell region MCR, the rear surface via 164 penetrating the upper interlayer insulating layer 162 may be formed. The rear surface via 164 formed in the cell region MCR may be electrically connected to the common source layer 110.

Rear surface pads 166 respectively connected to the rear surface vias 164 may be formed on the upper interlayer insulating layer 162. Thereafter, the passivation layer 168 covering the rear surface pads 166 may be formed on the upper interlayer insulating layer 162, and openings OP may be formed in the passivation layer 168 to expose the upper surfaces of the rear surface pads 166.

The semiconductor device 100a of FIG. 8 may be manufactured by using the processes described with reference to FIGS. 9A through 9G. The semiconductor device 100 of FIG. 7 may be almost the same as the semiconductor device 100a of FIG. 8, except for the shape of the upper end portion (refer to WLI_t in FIG. 7) of the stack separation insulating layer WLI and the shape of the upper end portion (refer to 130_t in FIG. 7) of the channel structure 130, and thus, the manufacturing process of the semiconductor device 100 may also be obtained by using a method similar to the manufacturing method illustrated in FIGS. 9A through 9G.

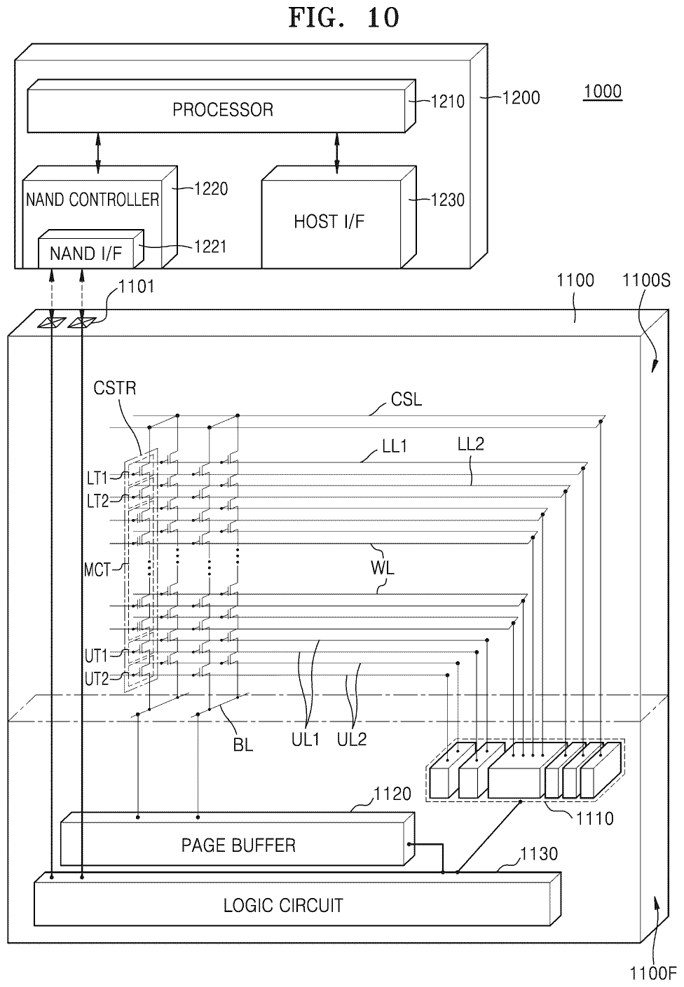

FIG. 10 is a schematic diagram of a data storage system 1000 including a semiconductor device 1100, according to an example embodiment.

Referring to FIG. 10, the data storage system 1000 may include one or more semiconductor devices 1100, and a memory controller 1200 electrically connected to the semiconductor device 1100. The data storage system 1000 may, for example, include a solid state drive (SSD) device, a universal serial bus (USB) device, a computing system, a medical device, or a communication device, which includes at least one semiconductor device 1100.

The semiconductor device 1100 may include a non-volatile semiconductor device, and the semiconductor device 1100 may, for example, include a NAND flash semiconductor device including one of the semiconductor devices 100 and 100a described with reference to FIGS. 1 through 9G. The semiconductor device 1100 may include a first structure 1100F and a second structure 1100S on the first structure 1100F. The first structure 1100F may include a periphery circuit structure including a row decoder 1110, a page buffer 1120, and a logic circuit 1130.

The second structure 1100S may have a memory cell structure including the bit line BL, the common source line CSL, the plurality of word lines WL, first and second gate upper lines UL1 and UL2, first and second ground selection lines LL1 and LL2, and a plurality of memory cell strings CSTR between the bit line BL and the common source line CSL.

In the second structure 1100S, each of the plurality of memory cell strings CSTR may include ground selection transistors LT1 and LT2 adjacent to the common source line CSL, string selection transistors UT1 and UT2 adjacent to the bit line BL, and a plurality of memory cell transistors MCT arranged between the ground selection transistors LT1 and LT2 and the string selection transistors UT1 and UT2. The number of ground selection transistors (e.g., LT1 and LT2) and the number of string selection transistors (e.g., UT1 and UT2) may be variously modified according to embodiments.

In some example embodiments, a plurality of ground selection lines LL1 and LL2 may be connected to gate electrodes of the ground selection transistors LT1 and LT2, respectively. The word line WL may be connected to a gate electrode of the memory cell transistor MCT. A plurality of string selection lines UL1 and UL2 may be connected to gate electrodes of the string selection transistors UT1 and UT2, respectively.

The common source line CSL, the plurality of ground selection lines LL1 and LL2, the plurality of word lines WL, and the plurality of string selection lines UL1 and UL2 may be connected to the row decoder 1110. The plurality of bit lines BL may be electrically connected to the page buffer 1120.

The semiconductor device 1100 may communicate with a memory controller 1200 via an input/output (I/O) pad 1101 electrically connected to the logic circuit 1130. The I/O pad 1101 may be electrically connected to the logic circuit 1130.

The memory controller 1200 may include a processor 1210, a NAND controller 1220, and a host interface (I/F) 1230. In some example embodiments, the data storage system 1000 may include a plurality of semiconductor devices 1100, and in this case, the memory controller 1200 may control the plurality of semiconductor devices 1100.

The processor 1210 may control the overall operation of the data storage system 1000 including the memory controller 1200. The processor 1210 may operate according to certain firmware and may control the NAND controller 1220 to access the semiconductor device 1100.

The NAND controller 1220 may include a NAND interface (I/F) 1221 processing communication with the semiconductor device 1100. Via the NAND I/F 1221, a control command for controlling the semiconductor device 1100, data to be written to the plurality of memory cell transistors MCT of the semiconductor device 1100, data to be read from the plurality of memory cell transistors MCT of the semiconductor device 1100, or the like may be transmitted. The host I/F 1230 may provide a communication function between the data storage system 1000 and an external host. When a control command is received from the external host via the host I/F 1230, the processor 1210 may control the semiconductor device 1100 in response to the control command.

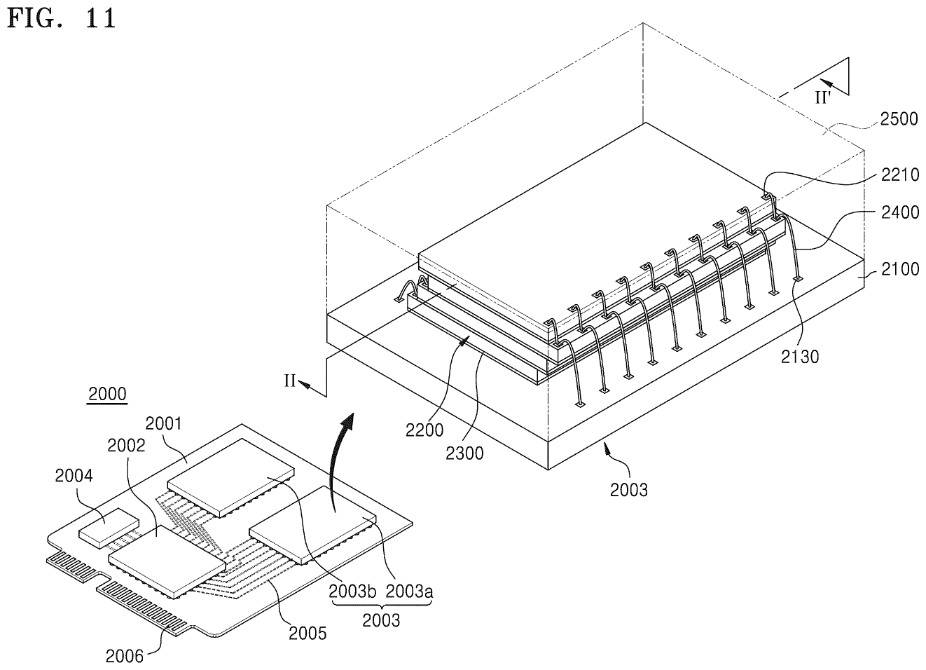

FIG. 11 is a schematic perspective view of a data storage system 2000 including a semiconductor device, according to an example embodiment.

Referring to FIG. 11, the data storage system 2000 according to an example embodiment may include a main substrate 2001, a memory controller 2002 mounted on the main substrate 2001, one or more semiconductor packages 2003, and dynamic random access memory (DRAM) 2004. The semiconductor package 2003 and the DRAM 2004 may be connected to the memory controller 2002 via a plurality of distribution patterns 2005 formed on the main substrate 2001.

The main substrate 2001 may include a connector 2006 including a plurality of pins combined with the external host. The number and arrangement of the plurality of pins of the connector 2006 may vary according to a communication interface between the data storage system 2000 and the external host. In some example embodiments, the data storage system 2000 may communicate with the external host according to any one of interfaces, such as USB, peripheral component interconnect (PCI)-express (PCI-E), serial advanced technology attachment (SATA), and M-Phy for a universal flash storage (UFS). In some example embodiments, the data storage system 2000 may operate by power supplied by the external host via the connector 2006. The data storage system 2000 may also further include a power management integrated circuit (PMIC), which distributes power supplied by the external host to the memory controller 2002 and the semiconductor package 2003.

The memory controller 2002 may write data to the semiconductor package 2003, or read data from the semiconductor package 2003, and may improve an operation speed of the data storage system 2000.

The DRAM 2004 may include a buffer memory for reducing a speed difference between the semiconductor package 2003, which is a data storage space, and the external host. The DRAM 2004 included in the data storage system 2000 may also operate as a kind of cache memory, and may also provide a space for temporarily storing data in a control operation on the semiconductor package 2003. When the DRAM 2004 is included in the data storage system 2000, the memory controller 2002 may further include a DRAM controller for controlling the DRAM 2004 in addition to the NAND controller for controlling the semiconductor package 2003.

The semiconductor package 2003 may include a first semiconductor package 2003a and a second semiconductor package 2003b, which are apart from each other. Each of the first and second semiconductor packages 2003a and 2003b may include a semiconductor package including a plurality of semiconductor chips 2200. Each of the first and second semiconductor packages 2003a and 2003b may include a package substrate 2100, the plurality of semiconductor chips 2200 on the package substrate 2100, an adhesive layer 2300 arranged under a lower surface of each of the plurality of semiconductor chips 2200, a connection structure 2400 electrically connecting the plurality of semiconductor chips 2200 to the package substrate 2100, and a molding layer 2500 covering the plurality of semiconductor chips 2200 and the connection structure 2400 on the package substrate 2100.

The package substrate 2100 may include a printed circuit board including a plurality of package upper pads 2130. Each of the plurality of semiconductor chips 2200 may include an input/output (I/O) pad 2210. The I/O pad 2210 may correspond to the I/O pad 1101 in FIG. 10. Each of the plurality of semiconductor chips 2200 may include at least one among the semiconductor devices 100 and 100a described with reference to FIGS. 1 through 9G.

In some example embodiments, the connection structure 2400 may include a bonding wire electrically connecting the I/O pad 2210 to the package upper pad 2130. Accordingly, in the first and second semiconductor packages 2003a and 2003b, the plurality of semiconductor chips 2200 may be electrically connected to each other by using a bonding wire method, and may be electrically connected to the package upper pad 2130 of the package substrate 2100. According to some example embodiments, in the first and second semiconductor packages 2003a and 2003b, the plurality of semiconductor chips 2200 may also be electrically connected to each other via a connection structure including through silicon vias TSV, instead of the connection structure 2400 of the bonding wire method.

In some example embodiments, the memory controller 2002 and the plurality of semiconductor chips 2200 may also be included in one package. In some example embodiments, the memory controller 2002 and the plurality of semiconductor chips 2200 may be mounted on an interposer substrate discretely different from the main substrate 2001, and the memory controller 2002 and the plurality of semiconductor chips 2200 may also be connected to each other via distribution formed on the interposer substrate.

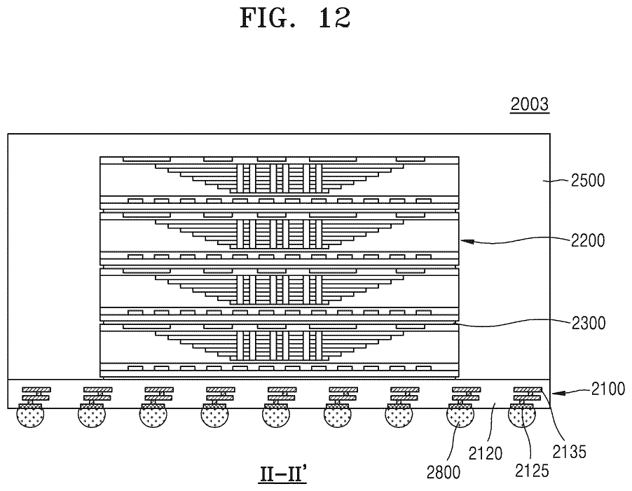

FIG. 12 is a schematic cross-sectional view of a semiconductor package 2003 according to an example embodiment. FIG. 12 is a cross-sectional view taken along line II-II′ in FIG. 11.

Referring to FIG. 12, in the semiconductor package 2003, the package substrate 2100 may include a printed circuit board. The package substrate 2100 may include a package substrate body unit 2120, the plurality of package upper pads (refer to 2130 in FIG. 11) arranged on an upper surface of the package substrate body unit 2120, a plurality of lower pads 2125 arranged under a lower surface of the package substrate body unit 2120 or exposed via the lower surface thereof, and a plurality of internal distributions 2135 electrically and respectively connecting the plurality of package upper pads (refer to 2130 in FIG. 11) to the plurality of lower pads 2125 in the package substrate body unit 2120. As illustrated in FIG. 12, the plurality of package upper pads 2130 may be electrically and respectively connected to a plurality of connection structures 2400. As illustrated in FIG. 12, the plurality of lower pads 2125 may be connected to the plurality of distribution patterns 2005 on the main substrate 2001 of the data storage system 2000 illustrated in FIG. 11 via a plurality of conductive bumps 2800, respectively. Each of the plurality of semiconductor chips 2200 may include at least one among the semiconductor devices 100 and 100a described with reference to FIGS. 1 through 9G.

Any functional blocks shown in the figures and described above may be implemented in processing circuitry such as hardware including logic circuits, a hardware/software combination such as a processor executing software, or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While the inventive concepts have been particularly shown and described with reference to some example embodiments thereof, it will be understood that various change in form and details may be made therein without departing from the spirit and scope of the following claims.

What is claimed is:

1. A semiconductor device comprising:
a periphery circuit structure; and
a cell structure on the periphery circuit structure, the cell structure including a cell region, a connection region, and a periphery circuit connection region,
wherein the cell structure comprises,
gate electrodes being apart from each other in the cell region in a vertical direction,
a plurality of channel structures configured to penetrate the gate electrodes in the cell region to extend in the vertical direction, each of the plurality of channel structures including a first end portion and a second end portion, the first end portion being adjacent to the periphery circuit structure and the second end portion being opposite to the first end portion,
a common source layer connected to the second end portion of each of the plurality of channel structures in the cell region, and
a hydrogen rich layer between the common source layer and an uppermost one of the gate electrodes, and
wherein a concentration of hydrogen (H) contained in the hydrogen rich layer is greater than a concentration of hydrogen (H) contained in the gate electrodes.

2. The semiconductor device of claim 1, wherein the hydrogen rich layer contains deuterium (D).

3. The semiconductor device of claim 1, wherein the hydrogen rich layer comprises silicon nitride.

4. The semiconductor device of claim 1, wherein the concentration of hydrogen (H) contained in the hydrogen rich layer is greater than the concentration of hydrogen (H) contained in the gate electrodes by 1% or more.

5. The semiconductor device of claim 1, wherein the concentration of hydrogen (H) contained in the hydrogen rich layer is greater than the concentration of hydrogen (H) contained in the gate electrodes by 20% or more.

6. The semiconductor device of claim 1, wherein the plurality of channel structures penetrate the hydrogen rich layer.

7. The semiconductor device of claim 1, wherein the hydrogen rich layer comprises,
an upper surface close to the second end portion of the plurality of channel structures that is entirely surrounded by the common source layer, and
a lower surface opposite to the upper surface and in contact with the uppermost one of the gate electrodes.

8. The semiconductor device of claim 1, wherein a thickness of the hydrogen rich layer is in a range of 50 Å to 500 Å.

9. The semiconductor device of claim 1, wherein the common source layer is on an upper surface of the hydrogen rich layer and on the second end portion of each of the plurality of channel structures.

10. The semiconductor device of claim 1, wherein the plurality of channel structures comprise a channel layer having a cylindrical shape extending in the vertical direction.

11. The semiconductor device of claim 1, wherein the plurality of channel structures, in a cross-section perpendicular to a horizontal direction in which the gate electrodes extend, have a trapezoidal shape in which a width thereof in the horizontal direction increases in a downward direction of the vertical direction.

12. The semiconductor device of claim 1, further comprising:
a conductive layer configured to conformally cover the common source layer;
an interlayer insulating layer configured to bury the cell structure;
a rear surface pad on the interlayer insulating layer; and
a rear surface via configured to penetrate the interlayer insulating layer and be connected to the rear surface pad and the conductive layer.

13. A semiconductor device comprising:
a substrate;
a periphery circuit structure on the substrate; and
a cell structure on the periphery circuit structure, the cell structure including a cell region, a connection region, and a periphery circuit connection region,
wherein the cell structure comprises,
gate electrodes being apart from each other in the cell region in a vertical direction,
a hydrogen rich layer on the gate electrodes,
a plurality of channel structures configured to penetrate the gate electrodes and the hydrogen rich layer in the cell region to extend in the vertical direction, each of the plurality of channel structures including a first end portion and a second end portion, the first end portion being adjacent to the periphery circuit structure, the second end portion being opposite to the first end portion,
a common source layer connected to the second end portion of each of the plurality of channel structures, the common source layer covering an upper surface of the hydrogen rich layer in the cell region, and
a conductive layer on an upper surface of the common source layer, and
wherein a concentration of hydrogen (H) and/or deuterium (D) contained in the hydrogen rich layer is greater than a concentration of hydrogen (H) contained in the gate electrodes.

14. The semiconductor device of claim 13, wherein the hydrogen rich layer comprises silicon nitride.

15. The semiconductor device of claim 13,
wherein the concentration of hydrogen (H) and/or deuterium (D) contained in the hydrogen rich layer is greater than the concentration of hydrogen (H) contained in the gate electrodes by 20% or more.

16. The semiconductor device of claim 13, wherein each of the plurality of channel structures comprise,
a channel layer having a cylindrical shape extending in the vertical direction,
a charge storage layer on an outer side wall of the channel layer, and
a blocking dielectric layer on an outer side wall of the charge storage layer.

17. The semiconductor device of claim 13, wherein a vertical cross-section of an upper end portion of the second end portion of each of the plurality of channel structures is trapezoidal.

18. The semiconductor device of claim 13, wherein
a thickness of the hydrogen rich layer is in a range of 50 Å to 500 Å,
a lower surface of the hydrogen rich layer is coplanar with an upper surface of an uppermost one of the gate electrodes, and
an upper surface of the hydrogen rich layer is coplanar with a lower surface of the common source layer.

19. A semiconductor device comprising:
a periphery circuit structure; and
a cell structure on the periphery circuit structure, the cell structure including a cell region, a connection region, and a periphery circuit connection region,
wherein the cell structure comprises,
gate electrodes being apart from each other in the cell region in a vertical direction,
a hydrogen rich layer on an uppermost one of the gate electrodes,
a channel structure configured to penetrate the gate electrodes and the hydrogen rich layer in the cell region to extend in the vertical direction, the channel structure including a first end portion and a second end portion, the first end portion being adjacent to the periphery circuit structure, the second end portion being opposite to the first end portion,
a pad portion extending from the gate electrodes, the pad portion having a step shape in the connection region,
an insulating wall extending at a boundary between the cell region and the connection region in the vertical direction, the insulating wall including an outer sidewall and an inner sidewall,
an insulating base layer in the connection region and the periphery circuit connection region, the insulating base layer contacting the outer sidewall of the insulating wall,
a common source layer in the cell region and connected to the second end portion of the channel structure and covering an upper surface of the hydrogen rich layer,
a conductive layer in the cell region and being conformal on the common source layer, and
in the connection region, a first plug configured to penetrate the pad portion and extend in the vertical direction, a first end portion of the first plug penetrating the insulating base layer, and
wherein a concentration of hydrogen (H) and/or deuterium (D) contained in the hydrogen rich layer is greater than a concentration of hydrogen (H) contained in the gate electrodes.

20. The semiconductor device of claim 19, wherein
the channel structure comprises a channel layer of a cylindrical shape and extending in the vertical direction, and
a portion of the channel layer at the second end portion of the channel structure is at a higher vertical level than the hydrogen rich layer.
